(19) United States
(12) Patent Application Publication
(10) Pub. No.: US 2016/0351311 A1
(43) Pub. Date: Dec. 1, 2016

(54) SUPERCONDUCTING COIL

(71) Applicant: HITACHI, LTD., Tokyo (JP)

(72) Inventor: Ryuya ANDO, Tokyo (JP)

(21) Appl. No.: 15/116,528

(22) PCT Filed: Feb. 5, 2015
(86) PCT No.: PCT/JP2015/053308

§ 371 Date: Aug. 4, 2016

(30) Foreign Application Priority Data
Feb. 6, 2014 (JP) 2014-020980

(51) Int. Cl. H01F 6/06; G01R 33/3815

(52) U.S. Cl. CPC H01F 6/06; G01R 33/3815

(57) ABSTRACT

A first superconducting coil (11) has a winding frame (13), a winding part (16) of a superconductor wire material (15) wound around the winding frame (13), and an insulating plate (25) inserted into the gap between the winding frame (13) and the winding part (16) of the superconductor wire material (15). The insulating plate (25) comprises a first insulating plate (21) and a second insulating plate (23) divided in the thickness direction. A low friction material (27) comprising a fluororesin sheet is inserted between the separation faces of the first insulating plate (21) and the second insulating plate (23) facing each other. It is thereby possible to provide a superconducting coil capable of simultaneously preventing quenching and reducing the number of manufacturing man-hours.

### TECHNICAL FIELD

The present invention relates to a superconducting coil constituting a superconducting magnet device.

### BACKGROUND ART

A superconducting magnet device includes a superconducting coil employing a superconducting wire rod whose electric resistance drops to zero at extremely low temperatures. The superconducting magnet device has a function of generating a strong and stable magnetic field in comparison with magnet devices of normal conductor coils by energizing the superconducting coil with a high electric current. Such superconducting magnet devices are being applied to technical fields in which stable high magnetic fields are necessary, such as nuclear magnetic resonance (NMR) and magnetic resonance imaging (MRI).

One of the elements essential in the designing of the superconducting coil as a main component of a superconducting magnet device is the inhibition of the so-called quench phenomenon. The quench phenomenon will be explained in detail below.

When normal conduction transition occurs for some reason in a part of a superconducting wire rod of a superconducting coil in the energized state, Joule heating occurs in the relevant part undergoing the normal conduction transition. The temperature of the relevant part of the superconducting wire rod starts to rise when the quantity of generated heat exceeds cooling capacity for maintaining the superconducting coil in the superconducting state. As a result, the temperature rises also in parts of the superconducting wire rod adjoining the relevant part due to heat conduction. This process occurs like a chain reaction, and eventually, the normal conduction transition occurs in most of the superconducting coil and the magnetic energy accumulated in the superconducting coil is discharged in the form of Joule heat. This is the quench phenomenon.

There are superconducting coils that are cooled down by use of a liquid refrigerant such as liquid helium. In such cases, the liquid helium is evaporated and gasified by the Joule heat and is released into the atmosphere.

As above, once the quench phenomenon occurs, the temperature of the superconducting coil rises and the refrigerant is lost due to the temperature rise. A procedure such as refilling with the refrigerant and recooling of the refrigerant is necessary for restarting the superconducting magnet device and the operation of the superconducting magnet device is impossible until the procedure is finished. Therefore, the inhibition of the quench phenomenon is regarded as one of the elements essential in the designing of the superconducting coil.

The normal conduction transition as the starting point of the quench phenomenon is caused by various factors. For example, when the superconducting coil itself is deformed by electromagnetic force that it receives, the superconducting coil slides with respect to a winding frame due to the deformation and frictional heat is caused by the sliding. The frictional heat caused as above is known as one of the factors raising the temperature of the superconducting coil.

Patent Literature 1 discloses a technology for reducing the amount of the frictional heat caused by the sliding of the superconducting coil with respect to the winding frame by inserting a low friction material between the winding frame and the superconducting coil. However, as the electromagnetic force increases with the increase in the capacity of the superconducting coil in recent years and the amount of the frictional heat increases accordingly, just reducing the friction might fall short of achieving sufficient quench phenomenon inhibiting effect.

Patent Literature 2 discloses a technology for reducing the amount of the frictional heat caused by the sliding of the superconducting coil with respect to the winding frame by inserting a spacer having an insulating function between the winding frame and the superconducting coil and inserting a low friction material between the spacer and the winding frame.

In cases of employing such structure in which a spacer having the insulating function is inserted between the winding frame and the superconducting coil as in Patent Literature 2, it is a precondition that the spacer is bonded to the superconducting coil. This is because the occurrence of sliding between the superconducting coil and the spacer causes frictional heat and that leads to a temperature rise of the superconducting coil.

Patent Literature 3 discloses a technology for a superconducting coil including a superconducting wire wound across multiple layers, insulating sheets each being made of an electrically insulating resin sheet and inserted between the layers of the superconducting wire, and adhesive resin filling gaps between the superconducting wire and the insulating sheets. The adhesiveness between the superconducting wire and the insulating sheets is enhanced by performing adhesion-facilitating treatment on the surfaces of the insulating sheets.

### PRIOR ART LITERATURE

### Patent Literature

Patent Literature 1: JP-H09-139309-A

Patent Literature 2: JP-2007-214466-A

Patent Literature 3: JP-2006-120828-A

### SUMMARY OF THE INVENTION

### Problem to be Solved by the Invention

In cases where it is required to generate a stable high magnetic field with high accuracy as in NMR or MRI, the dimensional accuracy required of the superconducting coil used for such purposes is generally extremely high in reality. Supposing that the configuration of the superconducting coil described in Patent Literature 1 or 2 is employed, the dimensional accuracy of the superconducting coil varies highly depending on the processing accuracy of the winding frame. However, attempting to secure high processing accuracy of the winding frame results in a great number of production man-hours.

Further, the number of production man-hours is necessitated to increase also when the adhesion-facilitating treatment is performed on the surfaces of the insulating sheets as disclosed in Patent Literature 3.

The object of the present invention, which has been made in consideration of the above-described situation, is to provide a superconducting coil capable of realizing the inhibition of the quench phenomenon and the reduction in the production man-hours at the same time.

### Means for Solving the Problem

To achieve the above-described object, a superconducting coil according to the present invention includes: a winding frame; a winding part of a superconducting wire rod wound around the winding frame; and an insulating plate inserted in a gap between the winding frame and the winding part. The insulating plate is separated in its thickness direction into multiple parts and is configured in such a manner that at least its opposing separation surfaces are slidable with respect to each other.

In the superconducting coil according to the present invention, the insulating plate is separated in its thickness direction into multiple parts. Thus, if a combination of insulating plates making a thickness corresponding to the gap between the winding frame and the winding part is selected from multiple types of insulating plates differing from each other in the thickness, for example, the dimensional error of the winding frame can be corrected by an appropriate combination of insulating plates. Consequently, the dimensional accuracy in regard to the arrangement of the winding part with respect to the winding frame can be kept at a high level independently of the processing accuracy of the winding frame needing a great number of man-hours, that is, even if the number of production man-hours for the processing of the winding frame is reduced.

Further, since the insulating plate is configured in such a manner that at least its opposing separation surfaces are slidable with respect to each other, the amount of frictional heat caused by the sliding at the opposing separation surfaces can be reduced and the frictional heat can be insulated effectively by an insulating plate situated near the winding parts of the superconducting wire rod. Consequently, the quench phenomenon inhibiting effect can be enhanced.

### Effect of the Invention

According to the present invention, a superconducting coil capable of realizing the inhibition of the quench phenomenon and the reduction in the production man-hours at the same time can be provided.

### BRIEF DESCRIPTION OF THE DRAWINGS

FIG. 1 is a diagram showing a vertical section of a superconducting coil according to a first embodiment of the present invention.

FIG. 2 is a diagram showing multilayer structure of an insulating plate included in the superconducting coil according to the first embodiment of the present invention.

FIG. 3 is a diagram showing a vertical section of a superconducting coil according to a second embodiment of the present invention.

### MODE FOR CARRYING OUT THE INVENTION

Superconducting coils according to embodiments of the present invention will be described in details below with reference to figures.

### Configuration of First Superconducting Coil 11 According to First Embodiment of Present Invention

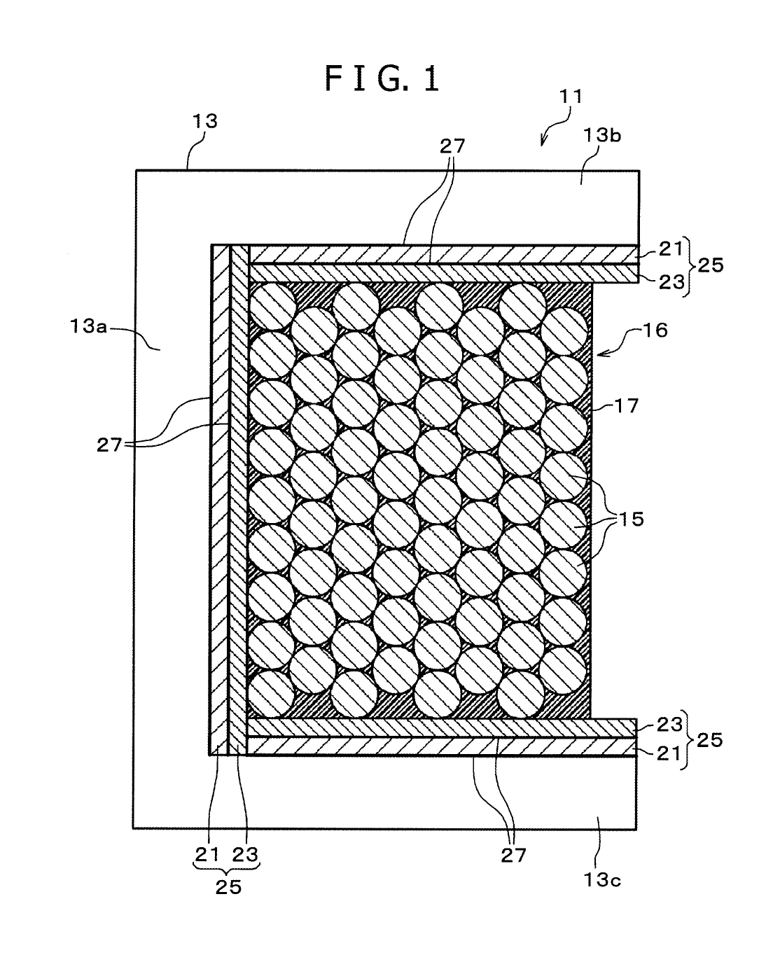

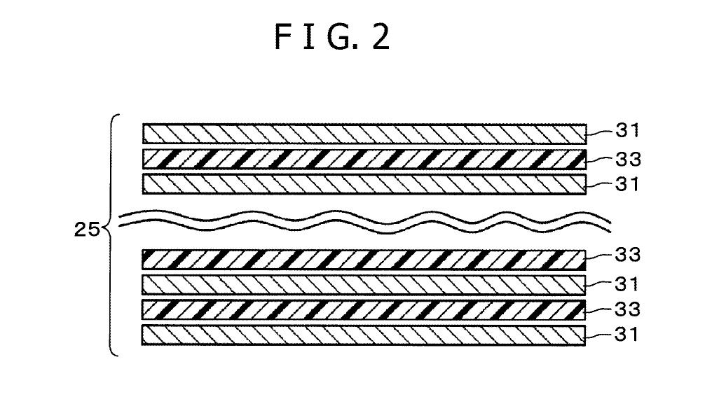

First, the configuration of a first superconducting coil 11 according to a first embodiment of the present invention will be described below with reference to FIGS. 1 and 2.

As shown in FIG. 1, the first superconducting coil 11 according to the first embodiment of the present invention includes a winding frame 13, a winding part 16 of a superconducting wire rod 15 circularly wound around the winding frame 13, and insulating plates 25 inserted in a gap between the winding frame 13 and the winding part 16 of the superconducting wire rod 15.

The winding frame 13 is made of nonmagnetic metal such as stainless steel. The winding frame 13 includes a basal part 13a in a substantially cylindrical shape and flange parts 13b and 13c extending circumferentially from the basal part 13a. The winding frame 13 is formed in such a manner that its vertical section is substantially in a U-shape. The winding part 16 of the superconducting wire rod 15 is accommodated in a substantially internal space, which is formed by the surface of u-shape of the winding frame 13. The winding part 16 of the superconducting wire rod 15 is integrated into one body by an impregnation process using resin 17 such as epoxy resin.

In the gap between the winding frame 13 and the winding part 16 of the superconducting wire rod 15, the insulating plates 25 are inserted to ensure electrical insulation and to hold the winding part 16 of the superconducting wire rod 15 at an appropriate position. And the shape of insulating plate 25 that is inserted between the basal part 13a and the winding part 16 is curved. The shape of the other insulting plates 25 that are inserted between the flange parts 13b and 13c, and winding part 16 are planar. The insulating plate 25 is separated in its thickness direction into multiple parts. Specifically, the insulating plate 25 is formed by joining together a first insulating plate 21 situated near the winding frame 13 and a second insulating plate 23 situated near the winding part 16 of the superconducting wire rod 15 at their separation surfaces opposing each other.

The first insulating plate 21 and the second insulating plate 23 have a common configuration.

Therefore, the first and second insulating plates 21 and 23 will collectively be referred to simply as insulating plates 25 when the discrimination between the first insulating plate 21 and the second insulating plate 23 is unnecessary in the explanation of the configuration of the first and second insulating plates 21 and 23.

As shown in FIG. 2, for example, the insulating plate 25 is formed by alternately stacking planar reinforcing materials 31 made of glass fiber and planar insulating materials 33 having low thermal conductivity and bonding them together into a planar shape by conducting an impregnation process by use of resin such as epoxy. As the insulating material 33, materials capable of securing insulation performance and thermal insulation performance at high levels, such as sheet-shaped polyimide, can be used preferably. Fiber-reinforced plastic is also usable as the material for the insulating material 33.

Incidentally, the first insulating plate 21 and the second insulating plate 23 separated in the thickness direction may either be made of a common material or materials different from each other.

Between the opposing separation surfaces of the first and second insulating plates 21 and 23, a low friction material 27 such as sheet-shaped fluorocarbon resin is inserted. With this configuration, even when the superconducting wire rod 15's winding part 16 itself is deformed by electromagnetic force that it receives during the operation of a first superconducting magnet device (unshown) including the first superconducting coil 11, sliding of the winding part 16 with respect to the winding frame 13 due to the deformation can be carried out between the opposing separation surfaces between which the low friction material 27 is inserted. As a result, the amount of frictional heat generated at the opposing separation surfaces can be reduced, by which the quench phenomenon inhibiting effect can be enhanced.

The second insulating plate 23 and the winding part 16 of the superconducting wire rod 15 are integrated into one body by keeping them in a state of being bonded together by an impregnation process using the resin 17 such as epoxy. For the bonding, in the second insulating plate 23 situated on the winding part 16's side, the surface facing the winding part 16 is desired to be treated with adhesion-facilitating treatment like the treatment disclosed in Patent Literature 3.

The first insulating plate 21 and the winding frame 13 may either be bonded together or not bonded together. In the first superconducting coil 11 according to the first embodiment of the present invention, the first insulating plate 21 and the winding frame 13 are not bonded together in order to facilitate the sliding of the winding part 16 with respect to the winding frame 13. Between the first insulating plate 21 and the winding frame 13, a low friction material 27 such as sheet-shaped fluorocarbon resin is inserted similarly to the gap between the opposing separation surfaces of the first and second insulating plates 21 and 23.

To sum up, when the superconducting wire rod 15's winding part 16 itself is deformed by electromagnetic force that it receives during the operation of the first superconducting magnet device (unshown) including the first superconducting coil 11, the sliding of the winding part 16 with respect to the winding frame 13 due to the deformation occurs between the opposing separation surfaces of the first and second insulating plates 21 and 23 and/or between the first insulating plate 21 and the winding frame 13 and does not occur between the second insulating plate 23 and the winding part 16 of the superconducting wire rod 15. Consequently, the sliding of the winding part 16 with respect to the winding frame 13 due to the deformation can be carried out between the surfaces between which the low friction material 27 is inserted.

Thus, by the first superconducting coil 11, the amount of the frictional heat caused by the aforementioned sliding can be reduced, by which the quench phenomenon inhibiting effect can be enhanced.

The thickness of the second insulating plate 23 is designed considering the fact that it should be possible to sufficiently insulate the quantity of the frictional heat caused by the aforementioned sliding. Specifically, the thickness dimension of the second insulating plate 23 may be determined by using a method like the one described in Patent Literature 2, for example. Here, the sliding heat quantity q can be defined as follows by using a slide distance δ, a surface pressure σ and a friction coefficient μ of the sliding surface:

q=μσδ (1)

The value of μ can be estimated from the material of the low friction material 27, the values of σ and δ can be estimated from the operating status of the first superconducting magnet device, and consequently, the sliding heat quantity q is calculated. Incidentally, the slide distance δ and the surface pressure σ change widely depending on the operating status of the first superconducting magnet device, that is, depending on the configuration of the superconducting magnet including the arrangement of the winding part 16 of the superconducting wire rod 15.

The sliding heat quantity q calculated as above is transmitted to the winding frame 13 and to the winding part 16 and works to raise the temperature of the winding part 16. In this case, the quench phenomenon due to the sliding heat quantity q can be inhibited if the temperature rise ΔT of the winding part 16 is less than a temperature tolerance, that is, an upper limit value ΔTmax capable of inhibiting the quench phenomenon in the winding part 16, as indicated by the following inequality:

ΔT<ΔTmax (2)

The temperature rise ΔT of the winding part 16 can be controlled by changing the thickness dimension of the second insulating plate 23. Specifically, the thermal insulation performance increases with the increase in the thickness dimension of the second insulating plate 23 and decreases with the decrease in the thickness dimension of the second insulating plate 23. If we focus only on the thermal insulation performance, it is desirable to set the thickness dimension of the second insulating plate 23 as thick as possible. However, the increase in the thickness dimension of the second insulating plate 23 leads to an increase in the cost for the second insulating plate 23, as well as an increase in the rigidity of the second insulating plate 23. Then, when the winding part 16 itself is deformed during the operation of the first superconducting magnet device, the second insulating plate 23 does not follow the deformation of the winding part 16, and thus there is the apprehension that the adhesive relationship between the second insulating plate 23 and the winding part 16 cannot be maintained. If the second insulating plate 23 and the winding part 16 detach from each other, the quench phenomenon can be caused by heat generated at the time of the detachment and heat generated by the mutual sliding of the second insulating plate 23 and the winding part 16 after the detachment.

Therefore, the thickness dimension of the second insulating plate 23 is desired to be set as thin as possible within the extent satisfying inequality (2).

The thickness dimension of the first insulating plate 21 is properly selected so as to fill the void corresponding to the gap between the winding frame 13 and the winding part 16 in consideration of the processing accuracy of the winding frame 13, the dimension of the gap between the winding frame 13 and the winding part 16, and the thickness dimension of the second insulating plate 23. Specifically, it is possible, for example, to prepare multiple types of insulating plates differing from each other in units of 0.1 mm in the thickness as the thickness dimension of the first insulating plate 21 and selectively use an insulating plate of an appropriate thickness depending on the processing accuracy of the winding frame 13 so that the wire winding of the winding part 16 with required dimensional accuracy is possible.

As above, even when the processing accuracy of the winding frame 13 is low, by selectively using a dimension capable of filling the void corresponding to the gap between the winding frame 13 and the winding part 16 as the thickness dimension of the first insulating plate 21, the position of arrangement of the winding part 16 with respect to the winding frame 13 can be adjusted to an appropriate position. Incidentally, the sum total of the thickness dimensions of the first insulating plate 21 and the second insulating plate 23 is set at a thickness dimension capable of securing the electrical insulation between the winding frame 13 and the winding part 16 in consideration of a maximum voltage that can occur on the occurrence of the quench phenomenon.

With such a configuration, a first superconducting coil 11 capable of realizing the inhibition of the quench phenomenon and the reduction in the production man-hours at the same time can be provided.

### Effect of First Superconducting Coil 11

The first superconducting coil 11 includes the winding frame 13, the winding part 16 of the superconducting wire rod 15 wound around the winding frame 13, and the insulating plates 25 inserted in the gap between the winding frame 13 and the winding part 16. The insulating plate 25 is separated in its thickness direction into multiple parts and is configured in such a manner that at least its opposing separation surfaces are slidable with respect to each other.

In the first superconducting coil 11, the insulating plate 25 is separated in its thickness direction into multiple parts. Thus, if a combination of insulating plates 25 making a thickness corresponding to the gap between the winding frame 13 and the winding part 16 is selected from multiple types of insulating plates 25 differing from each other in the thickness, for example, the dimensional error of the winding frame 13 can be corrected by an appropriate combination of insulating plates 25. In other words, in the gap between the winding frame 13 and the winding part 16, insulating plates 25 differing from each other in the thickness are combined together and inserted so as to fill the void corresponding to the gap. Consequently, the dimensional accuracy in regard to the arrangement of the winding part 16 with respect to the winding frame 13 can be kept at a high level independently of the processing accuracy of the winding frame 13 needing a great number of man-hours, that is, even if the number of production man-hours for the processing of the winding frame 13 is reduced.

Further, since the insulating plate 25 is configured in such a manner that at least its opposing separation surfaces are slidable with respect to each other, the amount of frictional heat caused by the sliding at the opposing separation surfaces can be reduced and the frictional heat can be insulated effectively by the second insulating plate 23 situated near the winding part 16 of the superconducting wire rod 15.

Furthermore, since the insulating plate 25 is separated in its thickness direction into multiple parts, the thickness of the second insulating plate 23 situated near the winding part 16 of the superconducting wire rod 15 can be made relatively thin in comparison with the conventional technology. As a result, the rigidity of the second insulating plate 23 situated near the winding part 16 of the superconducting wire rod 15 can be reduced. Accordingly, the adhesion detachment between the winding part 16 and the second insulating plate 23 due to the deformation of the winding part 16 accompanying the operation of the first superconducting magnet device hardly occurs and the adhesive relationship between the winding part 16 and the second insulating plate 23 is maintained. Consequently, the generation of heat due to the sliding at the adhesive surfaces is restrained and the quench phenomenon inhibiting effect can be enhanced.

Therefore, according to the first superconducting coil 11, a superconducting coil capable of realizing the inhibition of the quench phenomenon and the reduction in the production man-hours at the same time can be provided.

The following configuration may be employed in the first superconducting coil 11: Among the insulating plates 25 separated from each other in the thickness direction, the first insulating plate 21 inserted on the winding frame 13's side is an insulating plate selected from multiple types of insulating plates 25 differing from each other in the thickness so as to fill the void corresponding to the gap.

With such a configuration, since the first insulating plate 21 inserted on the winding frame 13's side is an insulating plate selected from multiple types of insulating plates 25 differing from each other in the thickness so as to fill the void corresponding to the gap, the dimensional error of the winding frame 13 can be corrected by the insulating plate selected so as to fill the void corresponding to the gap. Consequently, the dimensional accuracy in regard to the arrangement of the winding part 16 with respect to the winding frame 13 can be kept at a high level independently of the processing accuracy of the winding frame 13 needing a great number of man-hours, that is, even if the number of production man-hours for the processing of the winding frame 13 is reduced.

Further, the following configuration may be employed in the first superconducting coil 11: A low friction material 27 is inserted between opposing separation surfaces of the insulating plate 25 separated in its thickness direction into multiple parts.

With such a configuration, since the low friction material (e.g., sheet-shaped fluorocarbon resin) 27 is inserted between opposing separation surfaces of the insulating plate 25 separated in its thickness direction into multiple parts, the amount of frictional heat caused by the sliding at the opposing separation surfaces can be reduced. Consequently, the quench phenomenon inhibiting effect can be enhanced.

Furthermore, the following configuration may be employed in the first superconducting coil 11: The winding part 16 of the superconducting wire rod 15 is integrated into one body by an impregnation process using resin 17, and on the second insulating plate 23 situated on the winding part 16's side in the insulating plate 25 separated in its thickness direction into multiple parts, a surface facing the winding part 16 is treated with the adhesion-facilitating treatment.

With such a configuration, even when deformation of the winding part 16 occurs during the operation of the first superconducting magnet device, the adhesive detachment between the winding part 16 and the second insulating plate 23 due to the deformation of the winding part 16 hardly occurs and the adhesive relationship between the winding part 16 and the second insulating plate 23 is maintained. Consequently, the generation of heat due to the sliding at the adhesive surfaces is restrained and the quench phenomenon inhibiting effect can be enhanced.

### Configuration of Second Superconducting Coil 101 According to Second Embodiment of Present Invention

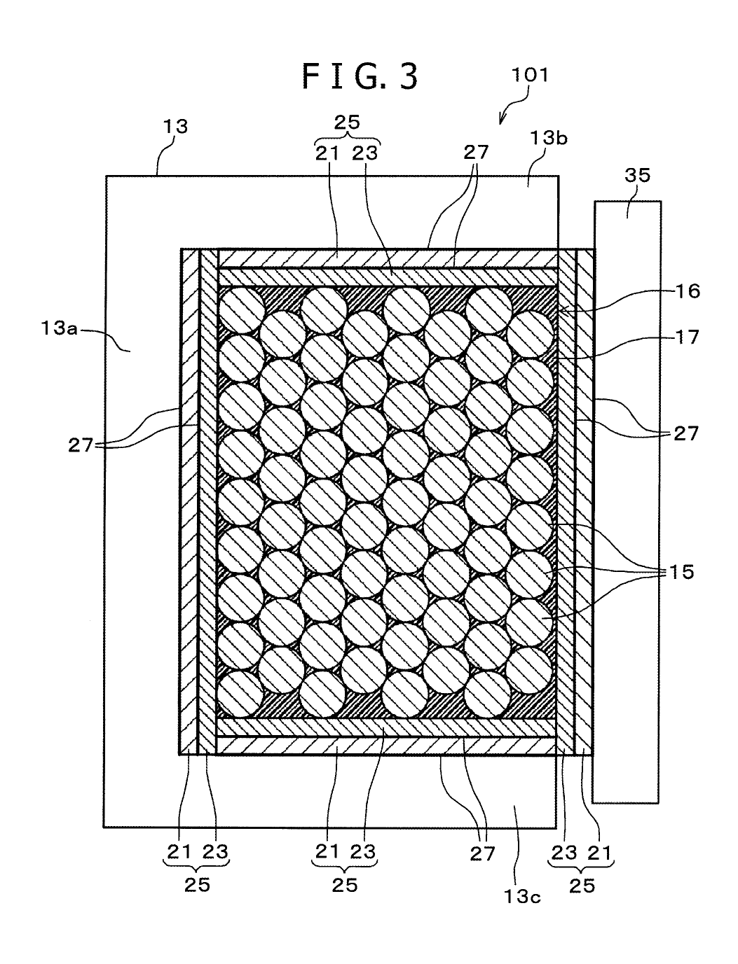

Next, the configuration of a second superconducting coil 101 according to a second embodiment of the present invention will be described below with reference to FIG. 3.

The second superconducting coil 101 according to the second embodiment of the present invention includes parts in common with the above-described first superconducting coil 11 according to the first embodiment. Thus, the following description of the second superconducting coil 101 according to the second embodiment will be given by explaining the difference between the first superconducting coil 11 and the second superconducting coil 101.

As shown in FIG. 3, the second superconducting coil 101 according to the second embodiment of the present invention is provided with a bind 35 situated to cover the substantially U-shaped space in the winding frame 13 from outside. The bind 35 is formed in a substantially cylindrical shape. The bind 35 functions to restrain the sliding of the winding part 16 with respect to the winding frame 13 caused by the electromagnetic force occurring in the winding part 16.

In the gap between the bind 35 and the winding part 16 of the superconducting wire rod 15, an insulating plate 25 is inserted similarly to the case of the first superconducting coil 11. Part of the configuration is in common with the first superconducting coil 11 in that the insulating plate 25 is formed of a first insulating plate 21 and a second insulating plate 23 and a low friction material 27 is inserted between the first insulating plate 21 and the second insulating plate 23. The bind 35 is attached to the winding part 16 by using a method like shrink fitting, for example. Therefore, surface pressure occurs between the bind 35 and the first and second insulating plates 21 and 23, the low friction material 27, and the winding part 16. The bind 35 is held by the surface pressure.

Incidentally, the method for determining the thickness dimensions of the first and second insulating plates 21 and 23 is the same as that for the first superconducting coil 11, and thus repeated explanation thereof is omitted here.

### Effect of Second Superconducting Coil 101

The second superconducting coil 101 includes the bind 35 situated to cover the substantially U-shaped space in the winding frame 13 from outside and an insulating plate 25 is inserted in the gap between the bind 35 and the winding part 16 of the superconducting wire rod 15. Therefore, when the superconducting wire rod 15's winding part 16 itself is deformed by electromagnetic force that it receives during the operation of a second superconducting magnet device (unshown) including the second superconducting coil 101, the sliding of the bind 35 with respect to the winding part 16 in the direction of opposing surfaces due to the deformation can be carried out between the surfaces of the first and second insulating plates 21 and 23 between which the low friction material 27 is inserted.

Thus, according to the second superconducting coil 101, when the winding part 16 itself is deformed by the electromagnetic force that it receives, the amount of frictional heat caused by the sliding of the bind 35 with respect to the winding part 16 in the direction of the opposing surfaces due to the deformation can be reduced and the quench phenomenon inhibiting effect can be enhanced by the thermal insulation effect borne by the second insulating plate 23.

Further, the following configuration may be employed in the second superconducting coil 101: Among the insulating plates 25 separated from each other in the thickness direction, the first insulating plate 21 inserted on the winding frame 13's side is an insulating plate selected from multiple types of insulating plates 25 differing from each other in the thickness so as to fill the void corresponding to the gap between the winding frame 13 and the winding part 16 of the superconducting wire rod 15.

With such a configuration, since the first insulating plate 21 inserted on the winding frame 13's side is an insulating plate selected from multiple types of insulating plates 25 differing from each other in the thickness so as to fill the void corresponding to the gap, the dimensional error of the winding frame 13 can be corrected by the insulating plate selected so as to fill the void corresponding to the gap. Consequently, the dimensional accuracy in regard to the arrangement of the winding part 16 with respect to the winding frame 13 can be kept at a high level independently of the processing accuracy of the winding frame 13 needing a great number of man-hours, that is, even if the number of production man-hours for the processing of the winding frame 13 is reduced.

### Other Embodiments

The above embodiments have been described to illustrate concrete examples of how the present invention is embodied. Thus, the technical scope of the present invention should not be interpreted restrictively due to the description of the embodiments. That is because the present invention can be carried out in a variety of forms without departing from its subject matter or its principal features.

For example, while examples of the insulating plate 25 formed of the first insulating plate 21 and the second insulating plate 23 were illustrated in the description of the first and second embodiments of the present invention, the present invention is not restricted to these examples. The insulating plate 25 may be formed of any number of parts as long as it is separated in its thickness direction into multiple parts.

Further, while the separation surfaces between the first insulating plate 21 and the second insulating plate 23 in the separation of the insulating plate 25 in its thickness direction into multiple parts are formed to squarely face the opposing surface of the first insulating plate 21 facing the winding frame 13 or the opposing surface of the second insulating plate 23 facing the winding part 16 in the examples illustrated in the description of the first and second embodiments of the present invention, the present invention is not restricted to these examples. The separation surfaces between the first insulating plate 21 and the second insulating plate 23 may also be formed to be inclined with respect to the opposing surface of the first insulating plate 21 facing the winding frame 13 or the opposing surface of the second insulating plate 23 facing the winding part 16.

### DESCRIPTION OF REFERENCE CHARACTERS

11: First superconducting coil (superconducting coil)
13: Winding frame
15: Superconducting wire rod
16: Winding part
21: First insulating plate (insulating plate)
23: Second insulating plate (insulating plate)
25: Insulating plate
27: Low friction material
35: Bind
101: Second superconducting coil (superconducting coil)

1. A superconducting coil comprising:
a winding frame;
a winding part of a superconducting wire rod wound around the winding frame; and
an insulating plate inserted in a gap between the winding frame and the winding part of the superconducting wire rod,
wherein the insulating plate is separated in its thickness direction into multiple parts and is configured in such a manner that at least its opposing separation surfaces are slidable with respect to each other.

2. The superconducting coil according to claim 1, wherein insulating plates differing from each other in thickness are combined together and inserted in the gap so as to fill a void corresponding to the gap.

3. The superconducting coil according to claim 1, wherein a low friction material is inserted between the opposing separation surfaces of the insulating plate separated in its thickness direction into multiple parts.

4. The superconducting coil according to claim 3, wherein the low friction material is a fluorocarbon resin sheet.

5. The superconducting coil according to claim 1, wherein
the winding part of the superconducting wire rod is integrated into one body by an impregnation process using resin, and
of an insulating plate situated near the winding part in the insulating plate separated in its thickness direction into multiple parts, a surface facing the winding part is treated with adhesion-facilitating treatment.

6. A superconducting coil comprising:
a winding frame;
a winding part of a superconducting wire rod wound around the winding frame; and
an insulating plate inserted in a gap between the winding frame and the winding part of the superconducting wire rod, wherein:
the winding frame is formed in such a manner that its cross section is substantially in a U-shape,
the winding part of the superconducting wire rod is accommodated in the substantially U-shaped space in the winding frame,
the insulating plate is separated in its thickness direction into multiple parts and is configured in such a manner that at least its opposing separation surfaces are slidable with respect to each other,
the superconducting coil comprises a bind situated to cover the substantially U-shaped space in the winding frame from outside, and
the insulating plate is inserted in a gap between the bind and the winding part of the superconducting wire rod.

7. The superconducting coil according to claim 6, wherein insulating plates differing from each other in thickness are combined together and inserted in the gap so as to fill a void corresponding to the gap.
